(19) United States
(12) Patent Application Publication
(10) Pub. No.: US 2005/0040473 A1
(43) Pub. Date: Feb. 24, 2005

(54) Semiconductor device and method of manufacturing the same

(76) Inventor: Tomohiro Saito, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/864,367

(22) Filed: Jun. 10, 2004

(30) Foreign Application Priority Data
Jun. 12, 2003 (JP) 2003-167803

(51) Int. Cl. H01L 29/76

(52) U.S. Cl. 257/384

(57) ABSTRACT

A semiconductor device is disclosed, which comprises a semiconductor substrate, a source/drain region formed in a surface region of the semiconductor substrate, a gate insulating film formed on the surface region of the semiconductor substrate, a gate electrode formed on the gate insulating film, and a silicide layer formed on a region of the source/drain region, which region is not covered by the gate electrode, an area of the silicide layer being smaller than that of the region not covered by the gate electrode.

### CROSS-REFERENCE TO RELATED APPLICATIONS

This application is based upon and claims the benefit of priority from prior Japanese Patent Application No. 2003-167803, filed Jun. 12, 2003, the entire contents of which are incorporated herein by reference.

### BACKGROUND OF THE INVENTION

1. Field of the Invention

The present invention relates to the structure of a semiconductor device and a method of manufacturing the same. In particular, the present invention relates to a silicide layer formed on a surface of source/drain regions of a MOS transistor, and to a method of forming the silicide layer.

2. Description of the Related Art

FIGS. 53-55 is a cross-sectional view to explain the process of manufacturing a low-resistance MOS transistor according to the prior art. A semiconductor substrate 101 such as a silicon substrate is formed with an isolation region (STI) 103 formed of a silicon oxide film. An element formation region defined by the isolation region 103 is formed with source/drain regions 108. A gate insulating film 104 such as a silicon oxide film is formed on part of the source/drain regions 108 and on portion of the element formation region between the source/drain regions 108. A polysilicon gate electrode 105 is further formed on the gate insulating film 104. The sidewall of the gate electrode 105 is formed with a sidewall insulating film 106 such as silicon oxide and nitride films (FIG. 53). A metal film 102 such as titanium, cobalt and nickel is deposited. The metal film 102 covers the foregoing source/drain regions 108, gate electrode and gate sidewall insulating film 106 (FIG. 54). The metal film 102 is heated using heat treatment of about 550° C. to obtain silicide of silicon and the metal film 102, thereby forming a metal silicide layer 109 (FIG. 55). A metal silicide layer is also formed on the polysilicon gate electrode 105. The metal silicide layer formed on the polysilicon gate electrode 105 is not shown for simplification. When a metal gate electrode is formed, no silicide layer is formed on the upper surface of the metal gate electrode.

Thereafter, metal films remaining as metal on the isolation region 103 and the sidewall insulating film 106 are removed using acid treatment. In the manner described above, the source/drain region is formed to have low resistance.

According to the prior art, a semiconductor device having the following structure is disclosed (see JPN. PAT. APLLN. KOAKI Publication No. 7-211898 (FIG. 1 and the explanation). In the semiconductor device, a diffusion layer having impurity concentration lower than the source/drain diffusion layer is formed between the source/drain diffusion layer and the gate. The diffusion layer having low impurity concentration is different from the source/drain diffusion layer, and formed as a non-salicide region. In addition, the following semiconductor integrated circuit device is proposed (see JPN. PAT. APLLN. KOAKI Publication No. 7-142589 (FIG. 1, FIG. 2 and their explanation). The device integrally includes a silicide MOS transistor in which source/drain diffusion layers are formed as silicide and a non-silicide MOS transistor.

With the development of silicon semiconductors, the scale down of transistors has advanced. In place of the conventional flat type transistors, SOI transistors, in particular, thin body silicon on insulator MOSFET (TB-SOI MOSFET) is studied. In the thin body silicon on insulator MOSFET, the channel of the transistor is formed into a thin film. However, a source/drain region (this means two regions, that is, source region and drain region) formed on the surface of the silicon semiconductor substrate have the following problem: namely the interface resistance between silicide layer and impurity diffusion region formed on the surface of the source/drain regions is high. As a result, it is impossible to sufficiently secure current driving force of transistors.

### BRIEF SUMMARY OF THE INVENTION

According to an aspect of the present invention, there is provided a semiconductor device comprising:
a semiconductor substrate;
a source/drain region formed in a surface region of the semiconductor substrate;
a gate insulating film formed on the surface region of the semiconductor substrate;
a gate electrode formed on the gate insulating film; and
a silicide layer formed on a region of the source/drain region, which region is not covered by the gate electrode, an area of the silicide layer being smaller than that of the region not covered by the gate electrode.

According to another aspect of the present invention, there is provided a method of manufacturing a semiconductor device, comprising:
forming an element formation region and an isolation region defining the element formation region in a semiconductor substrate;
forming a gate insulating film on the semiconductor substrate;
forming a gate electrode on the gate insulating film;
forming a sidewall insulating film on a sidewall of the gate electrode;
forming an impurity diffusion region forming a source/drain region in the semiconductor substrate by using the gate electrode and the sidewall insulating film as a mask;
removing a portion of the gate insulating film by using a resist pattern as a mask to expose a portion of the impurity diffusion region; and
forming a silicide layer on the exposed portion of the impurity diffusion region.

According to a further aspect of the present invention, there is provided a method of manufacturing a semiconductor device, comprising:
forming an element formation region and an isolation region defining the element formation region in a semiconductor substrate;
forming a buffer film on the semiconductor substrate;
forming a dummy gate electrode on the gate insulating film;
forming a sidewall insulating film on a sidewall of the dummy gate electrode;
forming an impurity diffusion region forming a source/drain region in the semiconductor substrate by using the gate electrode and the sidewall insulating film as a mask;
removing a portion of the buffer film by using a resist pattern as a mask to expose a portion of the impurity diffusion region;
forming a silicide layer on the exposed portion of the impurity diffusion region;
forming an interlayer insulating film to cover the silicide layer, the buffer film, the dummy gate electrode and the sidewall insulating film;
planarize the interlayer insulating film to expose an upper surface of the dummy gate electrode;
removing the dummy gate electrode and the buffer film under the dummy gate electrode to form a gate groove; and
forming in the gate groove a gate insulating film and a gate electrode on the gate insulating film.

### BRIEF DESCRIPTION OF THE SEVERAL VIEWS OF THE DRAWING

FIG. 1 is a plan view to explain a manufacturing process according to a first embodiment of the present invention;

FIG. 2 is a cross-sectional view to explain the manufacturing process according to the first embodiment, taken along the line 2-2 of FIG. 1;

FIG. 3 is a plan view to explain the manufacturing process according to the first embodiment;

FIG. 4 is a cross-sectional view to explain the manufacturing process according to the first embodiment, taken along the line 4-4 of FIG. 3;

FIG. 5 is a plan view to explain the manufacturing process according to the first embodiment;

FIG. 6 is a cross-sectional view to explain the manufacturing process according to the first embodiment, taken along the line 6-6 of FIG. 5;

FIG. 7 is a cross-sectional view to explain the manufacturing process according to the first embodiment, taken along the line 7-7 of FIG. 5;

FIG. 8 is a plan view to explain the manufacturing process according to the first embodiment;

FIG. 9 is a cross-sectional view to explain the manufacturing process according to the first embodiment, taken along the line 9-9 of FIG. 8;

FIG. 10 is a cross-sectional view to explain the manufacturing process according to the first embodiment, taken along the line 10-10 of FIG. 8;

FIG. 11 is a plan view to explain the manufacturing process according to the first embodiment;

FIG. 12 is a cross-sectional view to explain the manufacturing process according to the first embodiment, taken along the line 12-12 of FIG. 11;

FIG. 13 is a cross-sectional view to explain the manufacturing process according to the first embodiment, taken along the line 13-13 of FIG. 11;

FIG. 14 is a plan view to explain a manufacturing process according to a second embodiment of the present invention;

FIG. 15 is a cross-sectional view to explain the manufacturing process according to the second embodiment of the present invention, taken along the line 15-15 of FIG. 14;

FIG. 16 is a plan view to explain the process of manufacturing a semiconductor device according to the second embodiment;

FIG. 17 is a cross-sectional view to explain the manufacturing process according to the second embodiment of the present invention, taken along the line 17-17 of FIG. 16;

FIG. 18 is a plan view to explain the manufacturing process according to the second embodiment;

FIG. 19 is a cross-sectional view to explain the manufacturing process according to the second embodiment, taken along the line 19-19 of FIG. 18;

FIG. 20 is a cross-sectional view to explain the manufacturing process according to the second embodiment, taken along the line 20-20 of FIG. 18;

FIG. 21 is a plan view to explain the manufacturing process according to the second embodiment;

FIG. 22 is a cross-sectional view to explain the manufacturing process according to the second embodiment, taken along the line 22-22 of FIG. 21;

FIG. 23 is a plan view to explain the manufacturing process according to the second embodiment;

FIG. 24 is a cross-sectional view to explain the manufacturing process according to the second embodiment, taken along the line 24-24 of FIG. 23;

FIG. 25 is a cross-sectional view to explain the manufacturing process according to the second embodiment;

FIG. 26 is a cross-sectional view to explain the manufacturing process according to the second embodiment;

FIG. 27 is a cross-sectional view to explain the manufacturing process according to the second embodiment;

FIG. 28 is a cross-sectional view to explain the manufacturing process according to the second embodiment;

FIG. 29 is a cross-sectional view to explain a process of manufacturing a semiconductor device according to a third embodiment of the present invention;

FIG. 30 is a cross-sectional view to explain the manufacturing process according to the third embodiment;

FIG. 31 is a plan view to explain the manufacturing process according to the third embodiment;

FIG. 32 is a cross-sectional view to explain the manufacturing process according to the third embodiment, taken along the line 32-32 of FIG. 31;

FIG. 33 is a plan view to explain the manufacturing process according to the third embodiment;

FIG. 34 is a plan view to explain the manufacturing process according to the third embodiment;

FIG. 35 is a cross-sectional view to explain the manufacturing process according to the third embodiment, taken along the line 35-35 of FIG. 34;

FIG. 36 is a plan view to explain a process of manufacturing a semiconductor device according to a fourth embodiment of the present invention;

FIG. 37 is a cross-sectional view to explain the manufacturing process according to the fourth embodiment, taken along the line 37-37 of FIG. 36;

FIG. 38 is a plan view to explain a process of manufacturing a semiconductor device according to a fifth embodiment of the present invention;

FIG. 39 is a cross-sectional view to explain the manufacturing process according to the fifth embodiment, taken along the line 39-39 of FIG. 38;

FIG. 40 is a cross-sectional view to explain the manufacturing process according to the fifth embodiment, taken along the line 40-40 of FIG. 38;

FIG. 41 is a plan view to explain a process of manufacturing a semiconductor device according to a sixth embodiment of the present invention;

FIG. 42 is a cross-sectional view to explain the manufacturing process according to the sixth embodiment, taken along the line 42-42 of FIG. 41;

FIG. 43 is a cross-sectional view to explain the manufacturing process according to the sixth embodiment, taken along the line 43-43 of FIG. 41;

FIG. 44 is a plan view to explain a process of manufacturing a semiconductor device according to a seventh embodiment of the present invention;

FIG. 45 is a cross-sectional view to explain the manufacturing process according to the seventh embodiment, taken along the line 45-45 of FIG. 44;

FIG. 46 is a cross-sectional view to explain the manufacturing process according to the seventh embodiment, taken along the line 46-46 of FIG. 44;

FIG. 47 is a cross-sectional view to explain a manufacturing process according to a modification of the fifth embodiment, which corresponds to FIG. 39;

FIG. 48 is a cross-sectional view to explain a manufacturing process according to the modification of the fifth embodiment, which corresponds to FIG. 40;

FIG. 49 is a cross-sectional view to explain a manufacturing process according to a modification of the sixth embodiment, which corresponds to FIG. 42;

FIG. 50 is a cross-sectional view to explain a manufacturing process according to the modification of the sixth embodiment, which corresponds to FIG. 43;

FIG. 51 is a cross-sectional view to explain a manufacturing process according to a modification of the seventh embodiment, which corresponds to FIG. 45;

FIG. 52 is a cross-sectional view to explain a manufacturing process according to the modification of the seventh embodiment, which corresponds to FIG. 46;

FIG. 53 is a cross-sectional view to explain a process of manufacturing a conventional semiconductor device;

FIG. 54 is a cross-sectional view to explain the process of manufacturing a conventional semiconductor device; and

FIG. 55 is a cross-sectional view to explain the process of manufacturing a conventional semiconductor device.

### DETAILED DESCRIPTION OF THE INVENTION

Embodiments of the present invention will be described below with reference to the accompanying drawings.

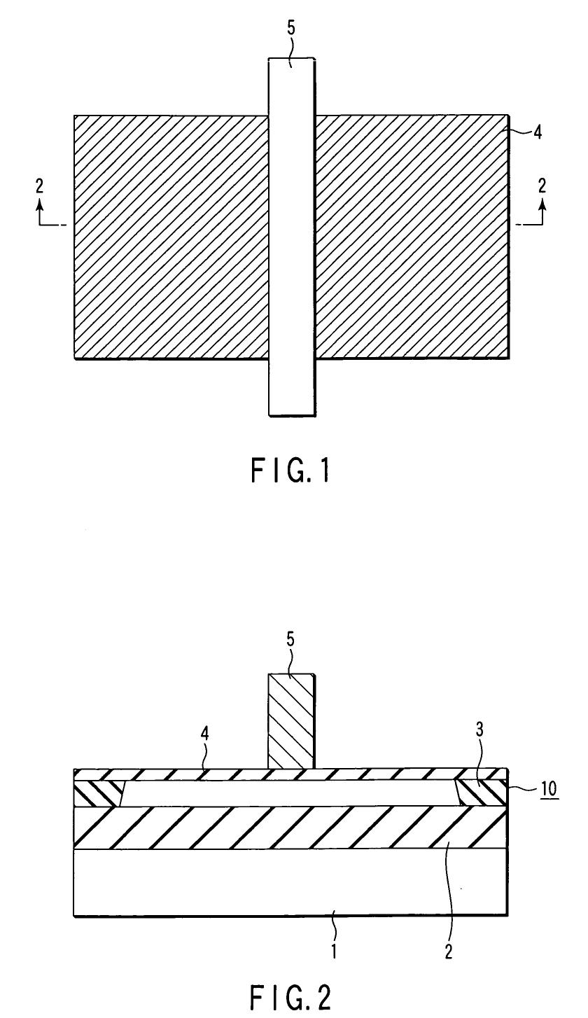

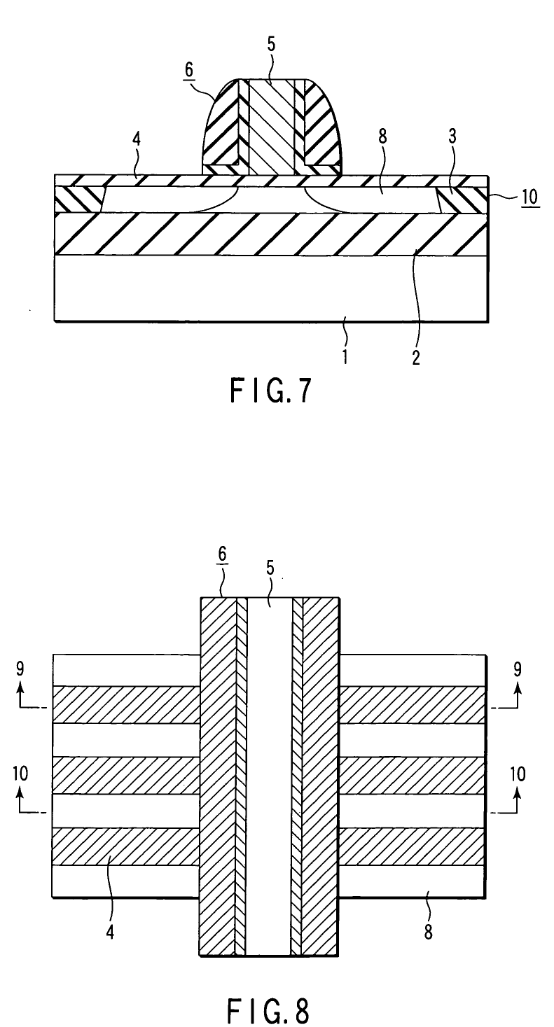

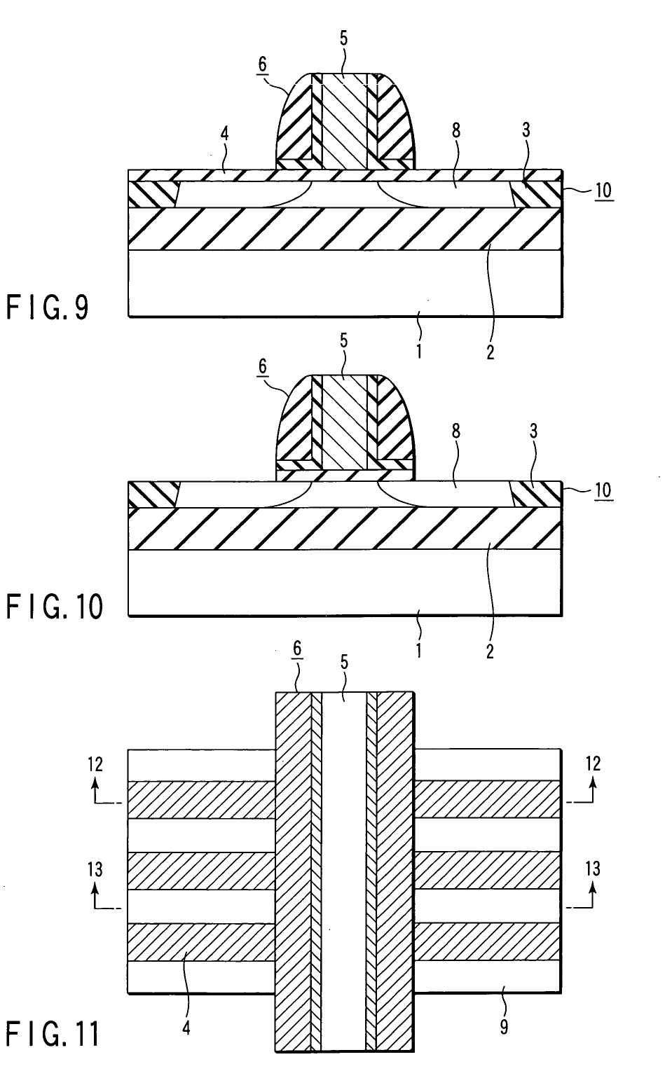

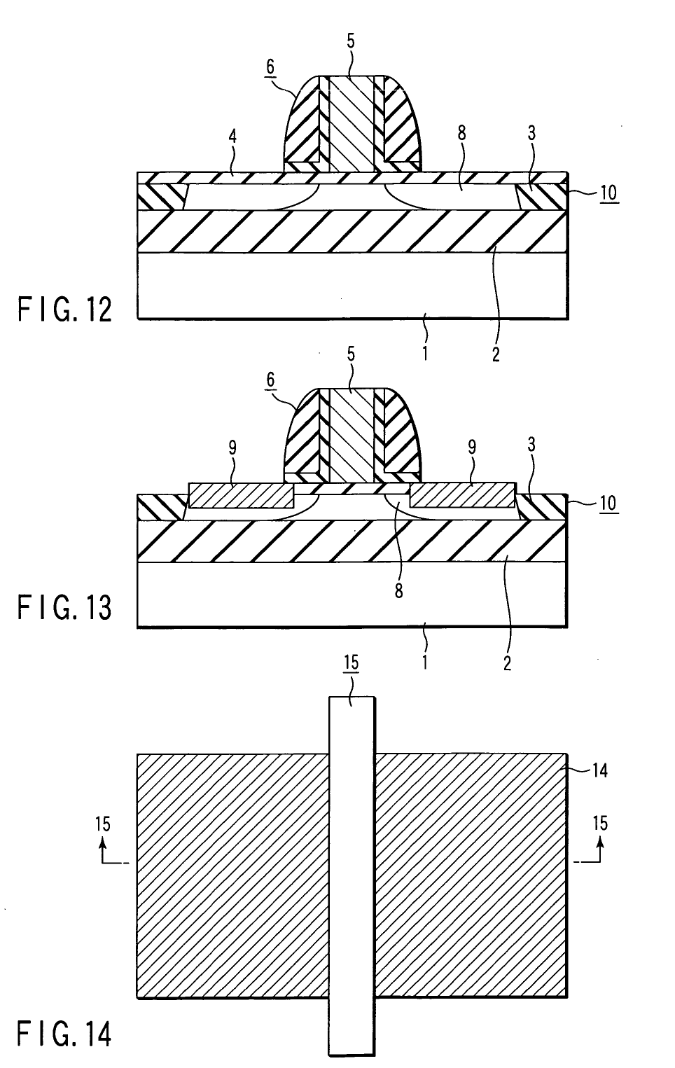

A first embodiment will be described below with reference to FIG. 1 to FIG. 13.

According to the first embodiment, a TB-SOI MOSFET is formed on a semiconductor layer on an SOI substrate.

A single silicon semiconductor layer (SOI layer) 10 is formed on a silicon semiconductor substrate 1 via an insulating film 2 such as a silicon oxide film. The silicon semiconductor layer 10 comprises a silicon activation layer and an element isolation region 3 defining the silicon activation layer. Here, a substrate comprising the silicon semiconductor layer 10, insulating layer 2 and semiconductor substrate 1 supporting the silicon semiconductor layer 10 is called an SOI substrate (FIGS. 1 and 2).

An element isolation region (STI: Shallow Trench Insulation) 3 is formed in the silicon semiconductor layer 10 using an already-known process. For example, the STI 3 is formed via the following process. A silicon nitride film used as a mask is deposited on the silicon semiconductor layer (SOI layer) via a buffer film. The foregoing silicon nitride film, buffer film and silicon semiconductor layer 10 are etched using a resist pattern-transfer process. The resist is removed, and thereafter, a silicon oxide film is deposited on the entire surface of the SOI substrate. Thereafter, the silicon oxide film is planarized using CMP (Chemical Mechanical Polishing). Finally, the silicon nitride film mask is removed, and thereby, the isolation region (STI) 3 formed of the silicon oxide film is provided.

When the silicon semiconductor layer (SOI layer) 10 of the used SOI substrate is thick, the silicon activation layer may be formed into a thin film using oxidization and etching as the need arises.

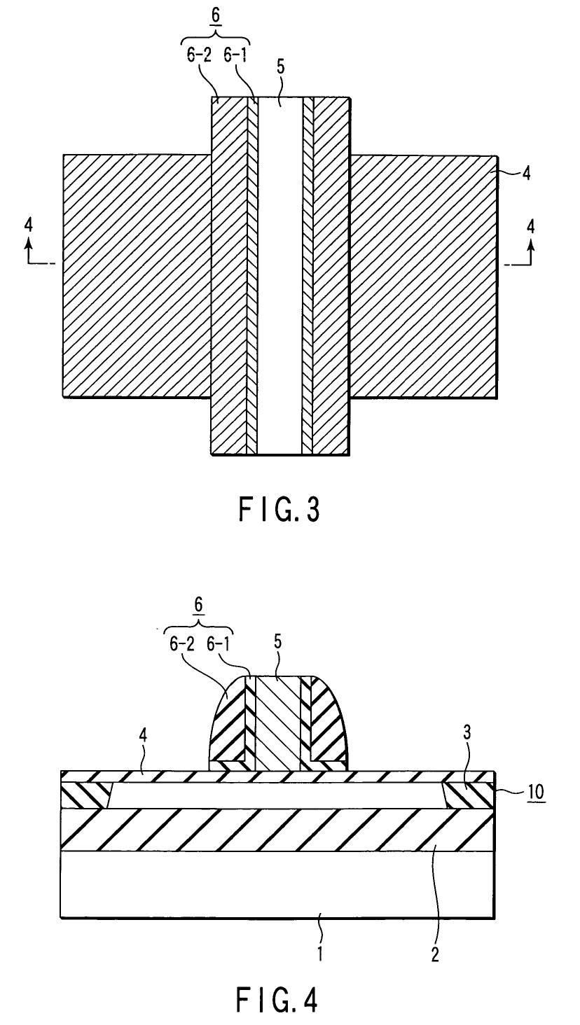

A gate insulating film 4 such as a silicon oxide film is deposited on the entire surface of the SOI substrate formed with the element isolation region 3. Polysilicon used as gate electrode material is deposited on the entire surface. The polysilicon is etched by using a resist pattern as a mask so that a polysilicon gate electrode 5 is formed (FIGS. 1 and 2). Extension ion implantation is carried out as the need arises, and further, crystal recovery annealing is carried out. A liner film 6-1 such as a silicon nitride (SiN) film is formed on the entire surface of the SOI substrate to cover the gate insulating film 4 and the gate electrode 5. Thereafter, for example, a TEOS film 6-2 is deposited on the liner film 6-1, and the TEOS film 6-2 and the liner film 6-1 are etched using anisotropic etching such as RIE (Reactive Ion Etching). By doing so, a gate sidewall insulating film 6 comprising TEOS film 6-2 and liner film 6-1 is formed on the sidewall of the gate electrode 5 (FIGS. 3 and 4). Impurity ions are implanted into a silicon activation layer using the gate sidewall insulating film 6 as a mask. Activation annealing is carried out to form source/drain regions, that is, impurity diffusion regions 8. In this case, the upper surface of the gate electrode 5, that is, polysilicon is exposed; however, the gate insulating film 4 remains on the upper surface of the impurity diffusion regions 8 (FIGS. 5, 6 and 7).

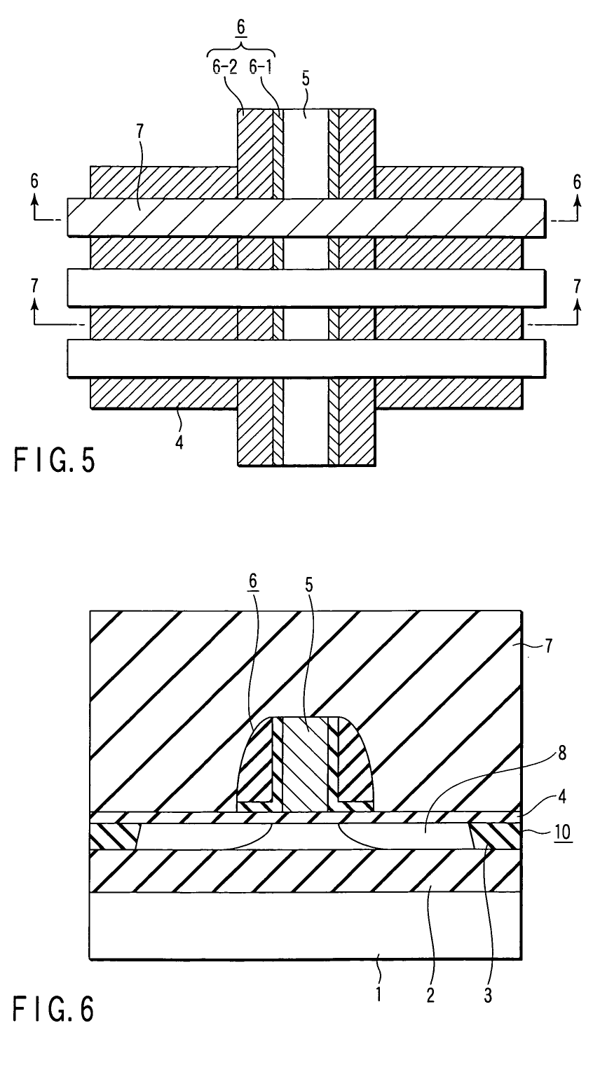

The gate insulating film 4 remaining on the upper surface of the impurity diffusion regions 8 is peeled off to have a stripe form so that the gate insulating film 4 is used as a mask. The process is carried out in the following manner if the gate insulating film 4 is formed of an oxide film. More specifically, a resist pattern 7 of a stripe form extending in a direction approximately perpendicular vertical to the gate electrode 5 (i.e., gate length direction) is formed on the oxide film (FIGS. 5 and 6). Side portions of the resist pattern 7 may be etched so that the width of the resist pattern 7 is decreased to thereby increase the silicide area. The gate insulating film of the region having no resist pattern 7 is removed using hydrofluoric acid and also using the resist pattern 7 as a mask, and thereby, the impurity diffusion regions 8 in the region having no resist pattern 7 are exposed. Thereafter, the resist pattern 7 is removed (FIGS. 8, 9 and 10).

For example, nickel is deposited on the entire surface of the SOI substrate to form a silicide layer. Heat treatment is carried out with respect to the deposited nickel, and thereby, nickel reacts with silicon of the impurity diffusion regions 8 covered with no gate insulating film 4 and the polysilicon of the polysilicon gate electrode 5. By doing so, a nickel silicide layer 9 is formed on the impurity diffusion regions 8 covered with no gate insulating film 4 (FIGS. 11, 12 and 13). Also, a nickel silicide layer is formed on the polysilicon gate electrode 5. The nickel silicide layer formed on the polysilicon gate electrode 5 is not shown for simplification. When a metal gate electrode is formed, no silicide layer is formed on the upper surface of the metal gate electrode.

Thereafter, non-reactive nickel is removed using a mixed solution of sulfuric acid and hydrogen peroxide water. Heat treatment is again carried out as the need arises. Finally, hydrofluoric acid treatment is carried out in order to remove the remaining gate insulating film. In this way, in the source/drain regions, the silicide portion and impurity diffusion portion are formed like stripes. Since each silicide layer is formed in the impurity diffusion layer (i.e., source/drain regions), not only the bottom portion but also the side portion of each silicide layer are in contact with the impurity diffusion layer. This results in increment of the total contact area of the silicide layer and the impurity diffusion layer, as compared with the case where a continuous silicide layer is formed on the entire surface of the impurity diffusion layer. The increment of the total contact area decreases the interface resistance between the silicide layer and the impurity diffusion layer.

Thereafter, the same process as for forming a normal transistor is carried out. More specifically, interlayer insulating film is formed on the entire surface of the SOI substrate, and thereafter, planarized. Patterning and etching are carried out to form contact holes. Titanium and titanium nitride are deposited, and heat treatment is carried out so that the titanium reacts with the silicide layer or impurity diffusion region. Thereafter, tungsten is deposited as a contact material and planarized so that the contact holes are formed with tungsten contacts. Titanium, titanium nitride and aluminum are formed on the entire surface of the SOI substrate as interconnections, and desired pattern is transferred to the titanium, titanium nitride and aluminum. Thereafter, anisotropic etching is carried out for the titanium, titanium nitride and aluminum, and thereby, interconnections are completed.

In the first embodiment, the silicide layer is formed like the stripe, and thereby, the contact area of the silicide layer and the impurity diffusion layer is increased. Therefore, it is possible to improve the current driving ability of an SOI type MOSFET.

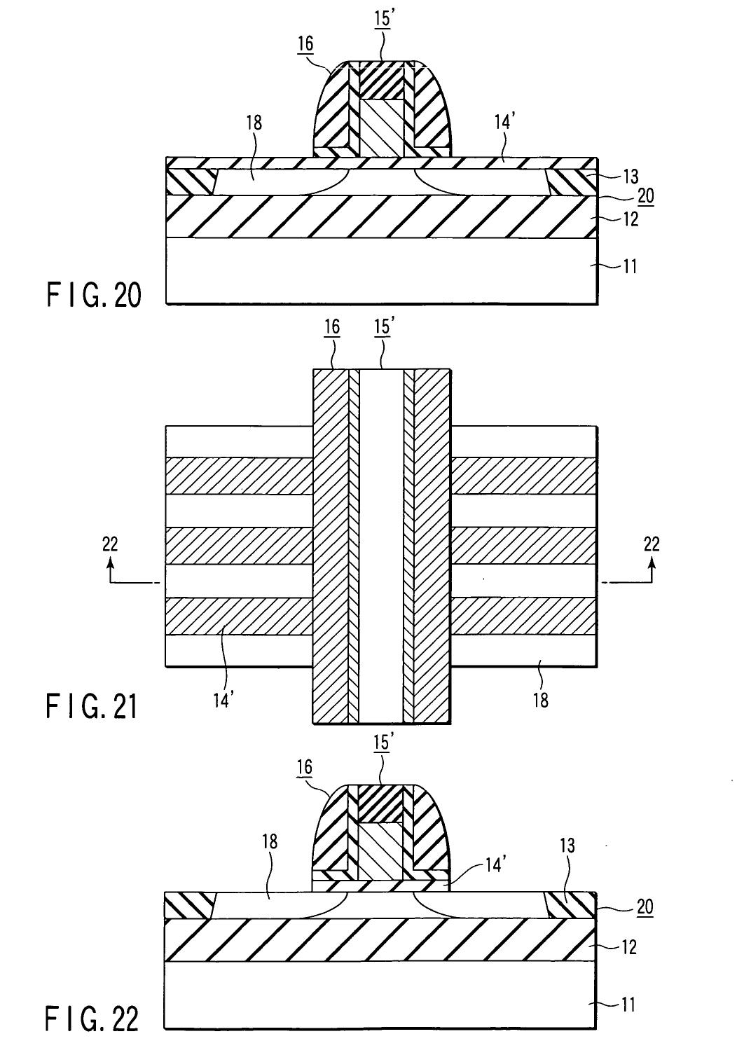

A second embodiment will be described below with reference to FIG. 14 to FIG. 28.

According to the second embodiment, a TB-SOI MOSFET is formed on a semiconductor layer on a semiconductor substrate. In the second embodiment, the gate is formed by damascene gate process.

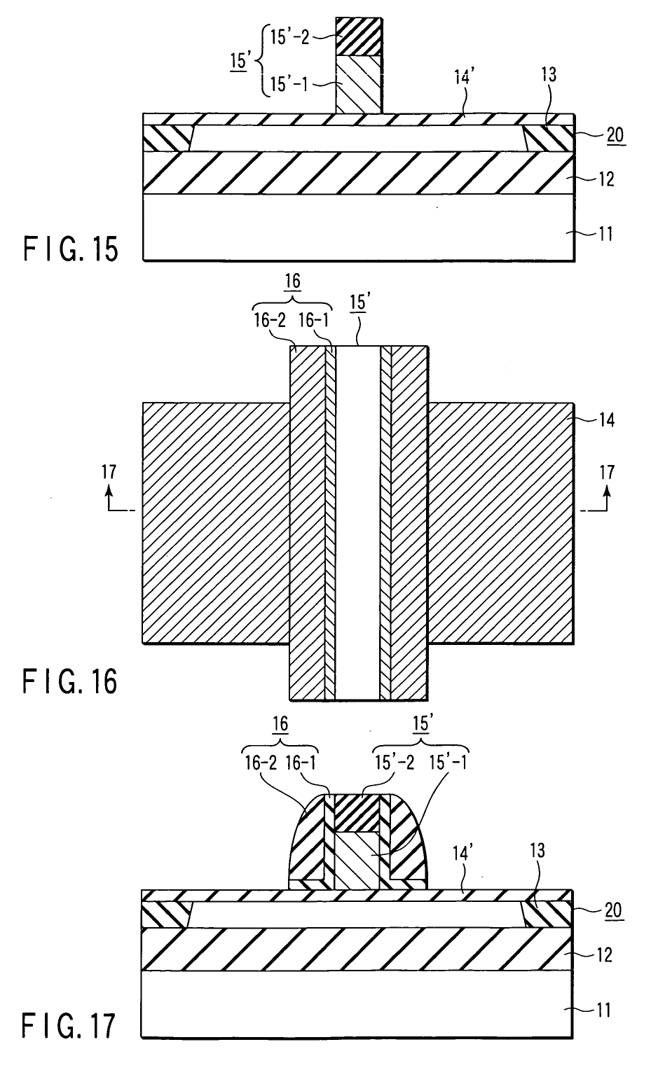

A single silicon semiconductor layer (SOI layer) 20 is formed on a silicon semiconductor substrate 11 via an insulating film 12 such as a silicon oxide film. The silicon semiconductor layer 20 comprises a silicon activation layer and an element isolation region 13 defining the silicon activation layer. Here, as in the first embodiment, a substrate comprising the silicon semiconductor layer 20, insulating layer 12 and semiconductor substrate 11 supporting the silicon semiconductor layer 20 is called an SOI substrate (FIGS. 14 and 15).

An isolation region (STI region) 13 is formed in the silicon semiconductor layer 20 using an already-known process, for example, the process described in the first embodiment. A buffer insulating film (buffer layer) 14′ such as a silicon oxide film is deposited on the entire surface of the SOI substrate formed with the element isolation region 13. Polysilicon used as gate electrode material is deposited on the entire surface of the SOI substrate. The polysilicon is etched by using a resist pattern as a mask so that a dummy gate electrode 15′ is formed (FIGS. 14 and 15). The dummy gate electrode 15′ has a multiplayer structure of a polysilicon layer 15′-1 and a silicon nitride film 15′-2 deposited on the polysilicon layer 15′-1. Extension ion implantation is carried out as the need arises, and further, crystal recovery annealing is carried out.

A liner film 6-1 such as a silicon nitride film is formed on the entire surface of the SOI substrate to cover the buffer layer 14′ and the dummy gate electrode 15′. Thereafter, a TEOS film 16-2 is deposited on the liner film 16-1, and the TEOS film 16-2 and the liner film 16-1 are etched using anisotropic etching such as RIE (Reactive Ion Etching). By doing so, a gate sidewall insulating film 16 comprising TEOS film 16-2 and liner film 16-1 is formed (FIGS. 16 and 17) on the sidewall of the dummy gate electrode 15′.

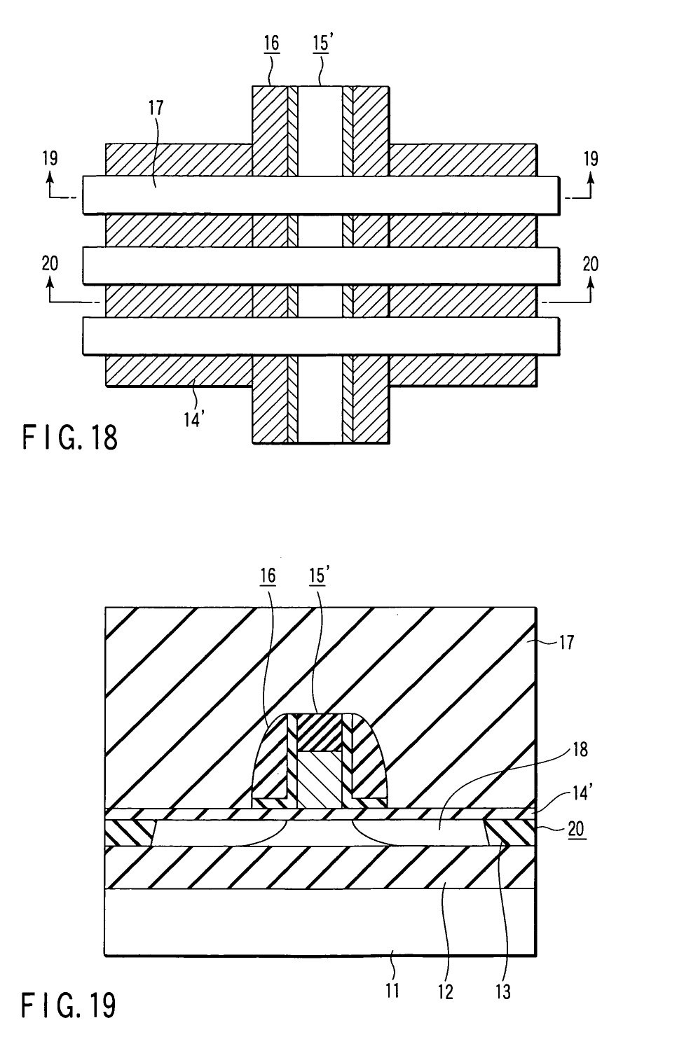

Impurity ions are implanted into a silicon activation layer using the gate sidewall insulating film 16 as a mask. Activation annealing is carried out to form source/drain regions, that is, impurity diffusion regions 18 (FIGS. 18 and 19). In this case, the upper surface of the gate electrode 15′, that is, polysilicon is exposed; however, the buffer insulating film 14′ remains on the upper surface of the impurity diffusion regions 18.

The buffer insulating film 14′ remaining on the upper surface of the impurity diffusion regions 18 is peeled off to have a stripe form so that the buffer insulating film 14′ is used as a mask. The process is carried out in the following manner if the gate insulating film 4 is formed of an oxide film. More specifically, a resist pattern 17 of a stripe form extending in a direction approximately perpendicular vertical to the dummy gate electrode 15′ (i.e., dummy gate length direction) is formed on the oxide film (FIGS. 18, 19 and 20). Side portions of the resist pattern 7 may be etched so that the width of the resist pattern 7 is decreased to thereby increase the silicide area. The buffer insulating film 14′ of the region having no resist pattern 17 is removed using hydrofluoric acid, and thereby, the impurity diffusion regions 18 of the region are exposed. Thereafter, the resist pattern 17 is removed (FIGS. 21 and 22).

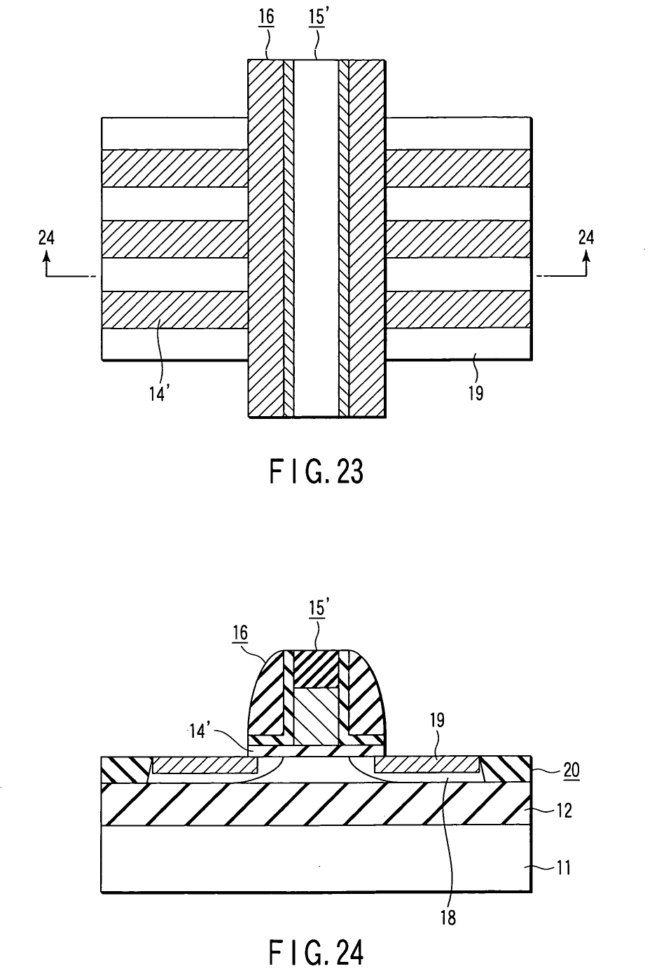

For example, nickel is deposited on the entire surface of the SOI substrate to form a silicide layer. Heat treatment is carried out with respect to the deposited nickel, and thereby, nickel reacts with the silicon of the impurity diffusion regions 18 covered with no buffer insulating film 14′. By doing so, a nickel silicide layer 19 is formed (FIG. 23 and FIG. 24) on the impurity diffusion regions 18. Thereafter, non-reactive nickel is removed using a mixed solution of sulfuric acid and hydrogen peroxide water. Heat treatment is again carried out as the need arises. Finally, hydrofluoric acid treatment is carried out in order to remove the remaining buffer insulating film. In this way, in the source/drain regions, the silicide portion and impurity diffusion portion are formed like stripes. Since each silicide layer 19 is formed in the impurity diffusion layer (i.e., source/drain regions) 18, not only the bottom portion but also the side portion of each silicide layer 19 are in contact with the impurity diffusion layer 18. This results in increment of the total contact area of the silicide layer 19 and the impurity diffusion layer 18, as compared with the case where a continuous silicide layer is formed on the entire surface of the impurity diffusion layer. The increment of the total contact area decreases the interface resistance between the silicide layer 19 and the impurity diffusion layer 18.

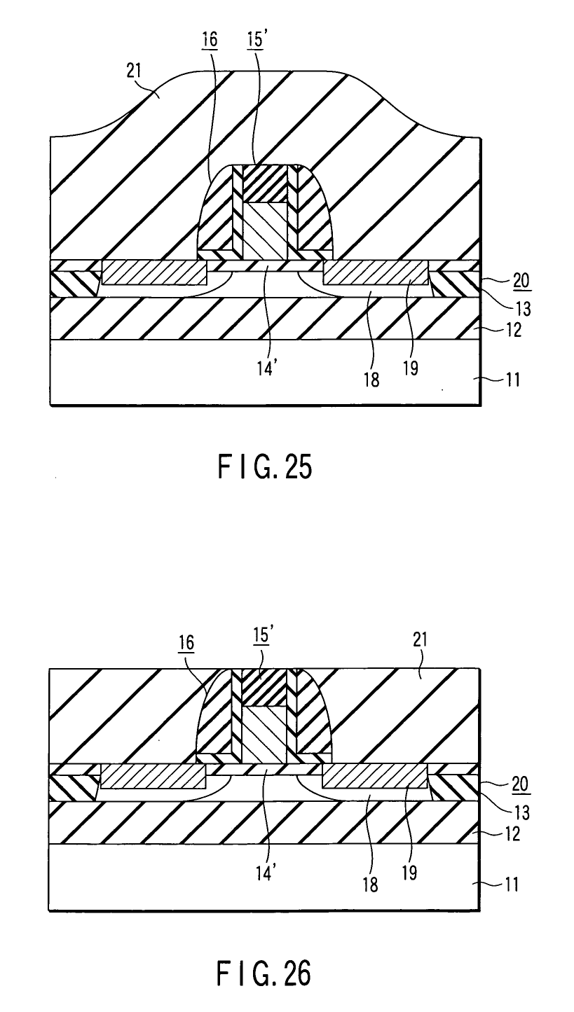

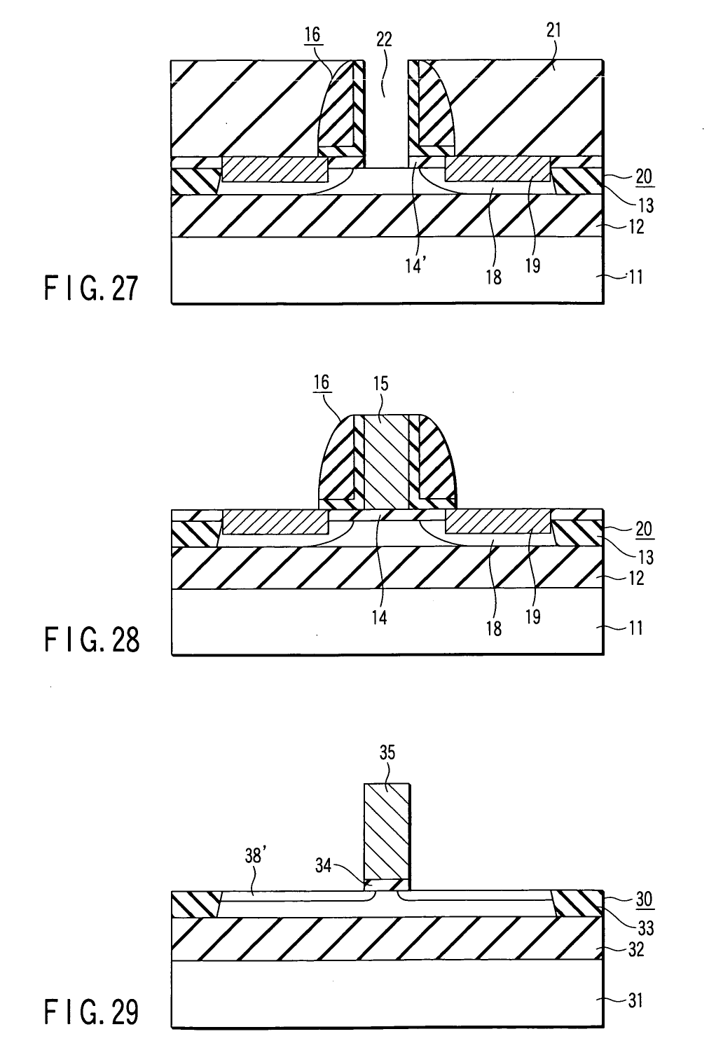

A silicon oxide film 21 as an interlayer insulating film is formed on the entire surface of the SOI substrate formed with the silicide layer 19 (FIG. 25). The interlayer insulating film 21 is planarized by using, for example, CMP (Chemical Mechanical Etching) to expose the upper surface of the dummy gate electrode 15′ (FIG. 26). The exposed dummy gate electrode 15′ is etched out and removed to provide a gate groove at the portion (FIG. 27). Thereafter, the buffer film 14 exposed at the bottom of the gate groove 22 is removed. A gate insulating film 14 such as a silicon oxide film and a gate electrode 15 such as a polysilicon layer are formed in the gate groove 22. The gate electrode 15 is formed on the gate insulating film 14. The gate electrode 15 may be formed by depositing a gate electrode material on the entire surface of the substrate and planarizing the gate electrode material by, for example, CMP, to provide an embedded gate electrode. Planarizing may be replaced with Patterning. A metal may be used as the gate electrode material. (FIG. 28)

Thereafter, the same process as for forming a normal transistor is carried out. More specifically, interlayer insulating film is formed on the entire surface of the SOI substrate, and thereafter, planarized. Patterning and etching are carried out to form contact holes. Titanium and titanium nitride are deposited, and heat treatment is carried out so that the titanium reacts with the silicide layer or impurity diffusion region. Thereafter, tungsten is deposited as a contact material and planarized so that the contact holes are formed with tungsten contacts. Titanium, titanium nitride and aluminum are formed on the entire surface of the SOI substrate as interconnections, and desired pattern is transferred to the titanium, titanium nitride and aluminum. Thereafter, anisotropic etching is carried out for the titanium, titanium nitride and aluminum, and thereby, interconnections are completed.

In the second embodiment, the silicide layer is formed like the stripe, and thereby, the contact area of the silicide layer and the impurity diffusion layer is increased. Therefore, it is possible to improve the current driving ability of an SOI type MOSFET. Moreover, a dummy gate electrode has a multi-layer structure of a polysilicon layer and a silicon nitride film deposited on the polysilicon layer, and thus no silicide layer is formed on the upper surface of the dummy gate electrode.

A third embodiment will be described below with reference to FIG. 29 to FIG. 35.

In this embodiment, the gate insulating film (oxide film) on the region in which the diffusion region is formed is removed before extension ion implantation.

According to this third embodiment, a TB-SOI MOSFET is formed on a semiconductor layer on a semiconductor substrate.

A single silicon semiconductor layer (SOI layer) 30 is formed on a silicon semiconductor substrate 31 via an insulating film 32 such as a silicon oxide film. The silicon semiconductor layer 30 comprises a silicon activation layer and an element isolation region 33 defining the silicon activation layer. Here, as in the first and second embodiments, a substrate comprising the silicon semiconductor layer 30, insulating layer 32 and semiconductor substrate 31 supporting the silicon semiconductor layer 30 is called an SOI substrate (FIG. 29).

An isolation region (STI region) 33 is formed in the silicon semiconductor layer 30 using an already-known process, for example, the process described in the first embodiment.

A gate insulating film 34 such as a silicon oxide film is deposited on the entire surface of the SOI substrate formed with the element isolation region 33. Polysilicon used as gate electrode material is deposited on the entire surface of the SOI substrate. The polysilicon is etched by using a resist pattern as a mask so that a polysilicon gate electrode 35 is formed (FIG. 29). Other than a part of the gate insulating film 34 on the element formation region, on which a gate electrode 35 is formed, is removed, and extension ion implantation is carried out, and further, crystal recovery annealing is carried out to form an extension region 38′ (FIG. 29).

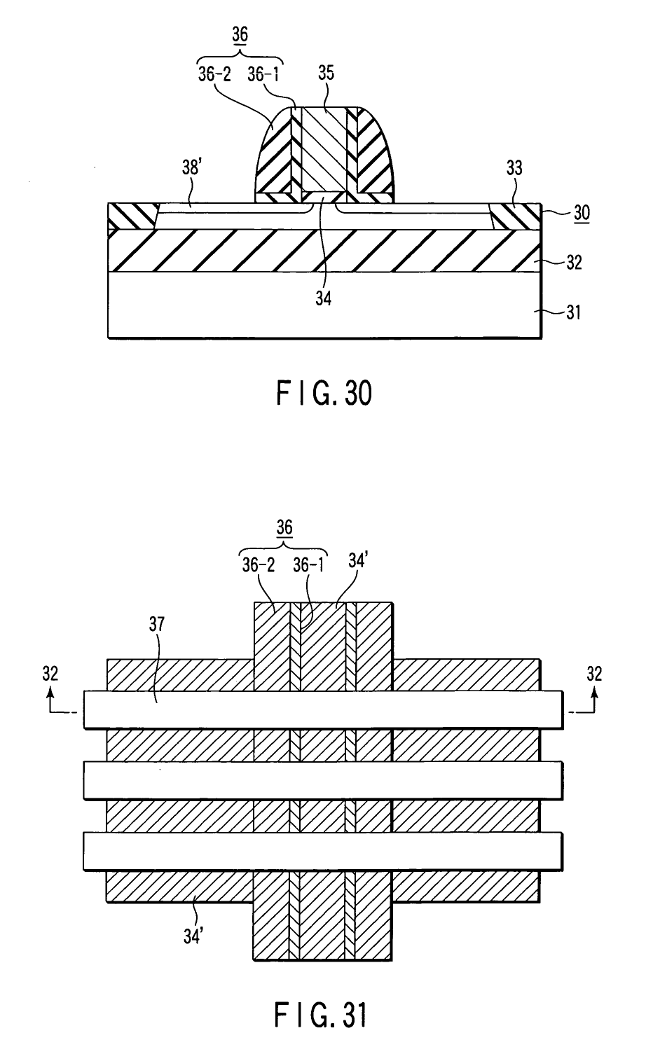

A liner film 36-1 such as a silicon nitride film is formed on the entire surface of the SOI substrate to cover the gate insulating film 34 and the gate electrode 35. Thereafter, a TEOS film 36-2 is deposited on the liner film 36-1, and the TEOS film 36-2 and the liner film 36-1 are etched using anisotropic etching such as RIE (Reactive Ion Etching). By doing so, a gate sidewall insulating film 36 comprising TEOS film 36-2 and liner film 36-1 is formed (FIG. 30) on the sidewall of the gate electrode 35.

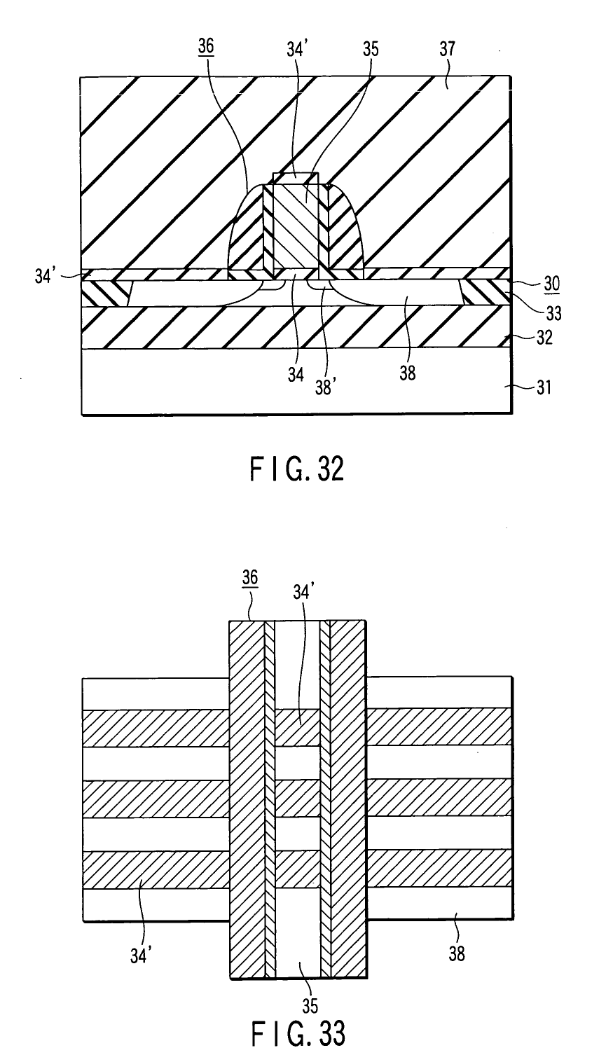

Impurity ions are implanted into a silicon activation layer using the gate sidewall insulating film 36 as a mask. Activation annealing is carried out to form source/drain regions, that is, impurity diffusion regions 38 (FIG. 32). In this case, the upper surface of the gate electrode 35, that is, polysilicon is exposed; similarly, the upper surface of the impurity diffusion regions 38 is also exposed. The extension region 38′ is covered by gate sidewall insulating film 36.

A buffer insulating film (buffer layer) 34′, for example, a silicon oxide film, is formed on the entire surface of the SOI substrate (FIG. 31). The buffer insulating film 34′ may be formed before implanting the impurity ions into the silicon activation layer to form the source/drain regions. The buffer insulating film 34′ is patterned to have a stripe form, for example, by using a resist pattern 37 as a mask (FIG. 31). As the result, the impurity diffusion regions 38 has a portion covered with the striped buffer insulating film 34′ and a portion in which the impurity diffusion regions 38 is exposed (FIG. 33). Similarly, the gate electrode 35 has a portion covered with the striped buffer insulating film 34′ and a portion in which the gate electrode 35 is exposed (FIG. 33).

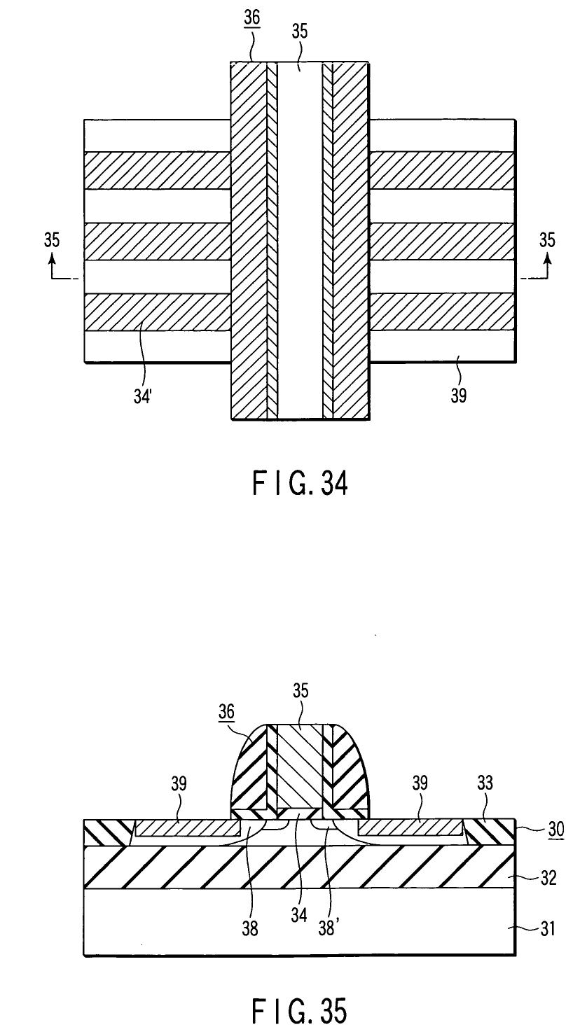

For example, nickel is deposited on the entire surface of the SOI substrate to form a silicide layer. Heat treatment is carried out with respect to the deposited nickel, and thereby, the nickel deposited on the impurity diffusion regions (source/drain regions) 38 reacts with the silicon of the impurity diffusion regions 38 covered with no buffer insulating film 34′. By doing so, a nickel silicide layer 39 is formed on the impurity diffusion regions 38 covered with no buffer insulating film 34′ (FIG. 34 and FIG. 35). Similarly, when the heat treatment is carried out, the nickel deposited on the gate electrode 35 reacts with the polysilicon of the gate electrode 35 covered with no buffer insulating film 34′. By doing so, a nickel silicide layer is formed on the gate electrode 35 covered with no buffer insulating film 34′. The nickel silicide layer formed on the gate electrode 35 is not shown for simplification. If no silicide layer is to be formed on the gate electrode 35, the buffer insulating film 34′ is not removed from the gate electrode 35, before depositing the nickel on the entire surface of the SOI substrate. In damascene gate process as used in the second embodiment, since a dummy gate has a multi-layer structure in which a silicon nitride film is formed on a polysilicon layer is provided, no silicide layer is formed on the upper surface of the dummy gate electrode. When a metal gate electrode is formed, no silicide layer is formed on the upper surface of the metal gate electrode.

Thereafter, non-reactive nickel is removed using a mixed solution of sulfuric acid and hydrogen peroxide water. Heat treatment is again carried out as the need arises. Finally, hydrofluoric acid treatment is carried out in order to remove the remaining buffer insulating film 34′. In this way, in the source/drain regions 38, the silicide portion and impurity diffusion portion are formed like stripes (FIG. 34). Since each silicide layer is formed in the impurity diffusion layer (i.e., source/drain regions), not only the bottom portion but also the side portion of each silicide layer are in contact with the impurity diffusion layer. This results in increment of the total contact area of the silicide layer and the impurity diffusion layer, as compared with the case where a continuous silicide layer is formed on the entire surface of the impurity diffusion layer. The increment of the total contact area decreases the interface resistance between the silicide layer and the impurity diffusion layer.

Thereafter, the same process as for forming a normal transistor is carried out, as described in the first embodiment, and finally interconnections are completed. When the gate electrode is to be formed by using damascene gate process as in the second embodiment, an interlayer insulating film is formed on the entire surface of the SOI substrate. Thereafter, the interlayer insulating film is planarized by CMP (Chemical Mechanical Etching) to exposed the dummy gate, and then the exposed dummy gate is removed to provide a groove in which a gate electrode is to be embedded.

As in the first and second embodiments, also in this embodiment, the silicide layer is formed like the stripe, and thereby, the contact area of the silicide layer and the impurity diffusion layer is increased. Therefore, it is possible to improve the current driving ability of an SOI type MOSFET.

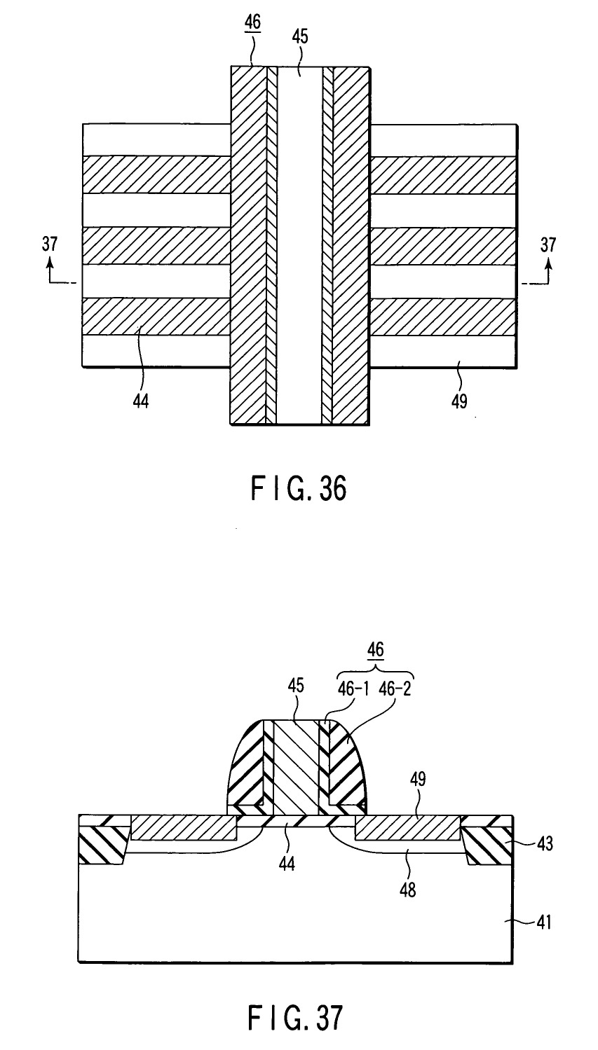

A fourth embodiment will be described below with reference to FIG. 36 and FIG. 37.

In this embodiment, an MOSFET is formed on a typical silicon semiconductor substrate in comparison with the first to third embodiments in which an MOSFET is formed on an SOI substrate.

An element isolation region 43 formed of, for example, silicon oxide, is formed in a silicon semiconductor substrate by using an already-known method. An MOSFET is formed in an element formation region i.e. an activation region, defined by the element isolation region 43.

A gate insulating film 44 such as a silicon oxide film is deposited on the entire surface of the semiconductor substrate 41 formed with the element isolation region 43. Polysilicon used as a gate electrode material is deposited on the entire surface of the gate insulating film 44. The polysilicon layer is etched by using a resist pattern as a mask so that a polysilicon gate electrode 45 is formed on the gate insulating film 44. In case of necessity, an extension ion implantation is carried out, and further, crystal recovery annealing is carried out to form an extension region.

A liner film 46-1 such as a silicon nitride film (SiN) is formed on the entire surface of the semiconductor substrate 41 to cover the gate insulating film 44 and the gate electrode 45. Thereafter, a TEOS film 46-2 is deposited on the liner film 46-1, and the TEOS film 46-2 and the liner film 46-1 are etched using anisotropic etching such as RIE (Reactive Ion Etching). By doing so, a gate sidewall insulating film 46 comprising TEOS film 46-2 and liner film 46-1 is formed on the sidewall of the gate electrode 45.

Impurity ions are implanted into the activation layer using the gate sidewall insulating film 46 as a mask. Activation annealing is carried out to form source/drain regions, that is, impurity diffusion regions 48. In this case, the upper surface of the gate electrode 45, that is, polysilicon is exposed; however, the gate insulating film 44 remains on the upper surface of the impurity diffusion regions 48.

The gate insulating film 44 remaining on the upper surface of the impurity diffusion regions 48 is peeled off to have a stripe form so that the gate insulating film 44 is used as a mask. The process is carried out in the following manner if the gate insulating film 44 is formed of an oxide film. More specifically, a resist pattern of a stripe form extending in a direction approximately perpendicular vertical to the gate electrode 45 (i.e., gate length direction) is formed on the oxide film. Side portions of the resist pattern may be etched so that the width of the resist pattern is decreased to thereby increase the silicide area. The gate insulating film of the region having no resist pattern is removed using hydrofluoric acid and also using the resist pattern as a mask, and thereby, the impurity diffusion regions 48 in the region having no resist pattern are exposed. Thereafter, the resist pattern is removed.

For example, nickel is deposited on the entire surface of the semiconductor substrate 41 to form a silicide layer. Heat treatment is carried out with respect to the deposited nickel, and thereby, nickel reacts with the silicon of the impurity diffusion regions 48 covered with no gate insulating film 44 and the polysilicon of the polysilicon gate electrode 45. By doing so, a nickel silicide layer 49 is formed on the impurity diffusion regions 48 covered with no gate insulating film 44. Also, a nickel silicide layer is formed on the polysilicon gate electrode 45. The nickel silicide layer formed on the polysilicon gate electrode 45 is not shown for simplification. When a metal gate electrode is formed, no silicide layer is formed on the upper surface of the metal gate electrode.

Thereafter, non-reactive nickel is removed using a mixed solution of sulfuric acid and hydrogen peroxide water. Heat treatment is again carried out as the need arises. Finally, hydrofluoric acid treatment is carried out in order to remove the remaining gate insulating film. In this way, in the source/drain regions, the silicide portion and impurity diffusion portion are formed like stripes. Since each silicide layer is formed in the impurity diffusion layer (i.e., source/drain regions), not only the bottom portion but also the side portion of each silicide layer are in contact with the impurity diffusion layer. This results in increment of the total contact area of the silicide layer and the impurity diffusion layer, as compared with the case where a continuous silicide layer is formed on the entire surface of the impurity diffusion layer. The increment of the total contact area decreases the interface resistance between the silicide layer and the impurity diffusion layer.

In this embodiment, the gate insulating film used as mask is not formed on the gate electrode. If there is no need of forming the silicide layer on the upper surface of the gate electrode, the upper surface of the gate electrode is covered with a so-called cap film. By doing so, the upper surface of the gate electrode is not formed as silicide. If the silicide layer is required, a metal film such as nickel may be deposited on the upper surface of the gate electrode.

As in the first to third embodiments, also in this embodiment, the silicide layer is formed like the stripe, and thereby, the contact area of the silicide layer and the impurity diffusion layer is increased. Therefore, it is possible to improve the current driving ability of an SOI type MOSFET.

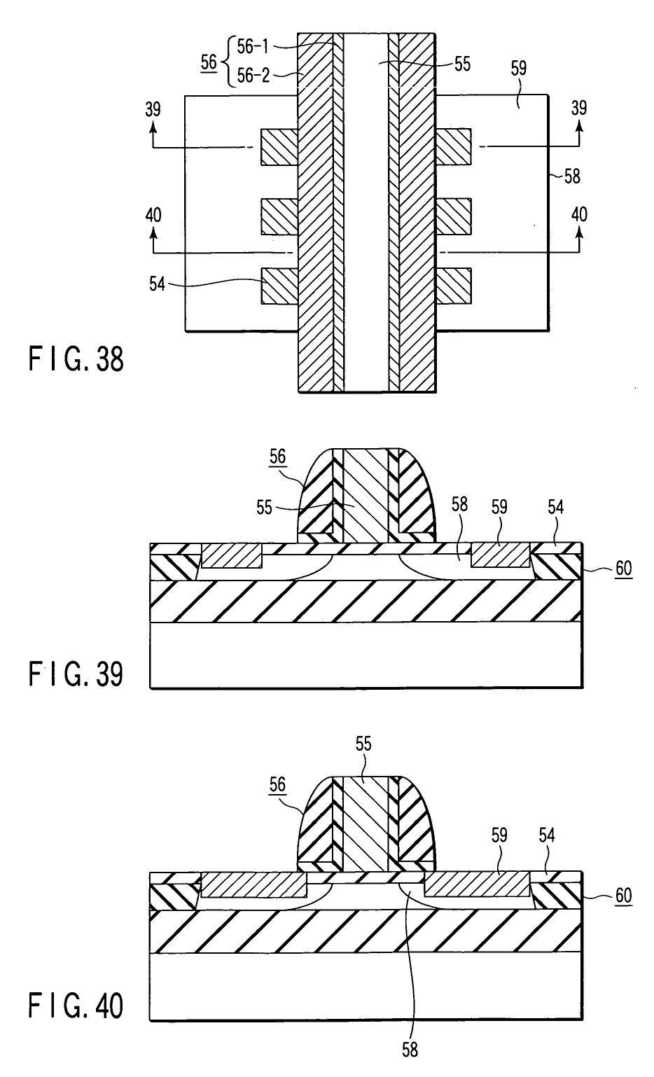

A fifth embodiment will be explained below with reference to FIG. 38 to FIG. 40.

In the first to fourth embodiments, the silicide layer has a stripe form. The form of the silicide layer is not limited to a stripe form. According to the fifth embodiment, the silicide adjacent to the gate electrode is formed into a comb shape.

In this embodiment, a MOSFET is applied in a case where it is formed on an SOI substrate; however, a MOSFET may be applied in a case where it is formed on a general silicon semiconductor substrate.

A semiconductor layer 60 of an SOI substrate is formed with an isolation region 53 comprising silicon oxide film using already-known process. The MOSFET is formed at an element formation region defined by the isolation region 53.

A gate insulating film 54 such as a silicon oxide film is formed on the semiconductor layer 60 formed with the isolation region 53. A polysilicon gate electrode 55 is formed on the gate insulating film on the element formation region. A gate sidewall insulating film 56 is formed on the sidewall of the gate electrode 55. The gate sidewall insulating film 56 is composed of TEOS film 56-2 and liner film 56-1 such as a silicon nitride film. The element formation region is formed with an impurity diffusion region 58 comprising source/drain regions. The foregoing gate electrode 55 and gate sidewall insulating film 56 are formed on part of the source/drain regions 58 and on portion of the element formation region between the source/drain regions 58. The impurity diffusion region 58 is formed with a silicide layer 59 in order to achieve a low resistance. Also, a nickel silicide layer is formed on the polysilicon gate electrode 55. The nickel silicide layer formed on the polysilicon gate electrode 55 is not shown for simplification. When a metal gate electrode is formed, no silicide layer is formed on the upper surface of the metal gate electrode.

The upper surface of the exposed impurity diffusion region is provided with a region formed with no silicide layer. The region of the impurity diffusion region formed with no silicide layer is covered by the gate insulating film 54. That is, the portion covered by the gate insulating film 54 is a non-silicide region of the impurity diffusion region. The non-silicide region is adjacent to the gate electrode 55 and has a comb shape at the portion adjacent to the gate electrode 55. Accordingly, the part of the silicide layer 59 adjacent to the gate electrode 55 has a comb shape.

In this fifth embodiment, the area of the exposed impurity diffusion region is made larger than that of the silicide layer to provide a region formed with no silicide layer. By doing so, the contact area of the silicide layer and the impurity diffusion region is increased. Therefore, it is possible to effectively improve the current driving ability of the MOSFET.

Various shapes are given as the shape of region formed with no silicide layer.

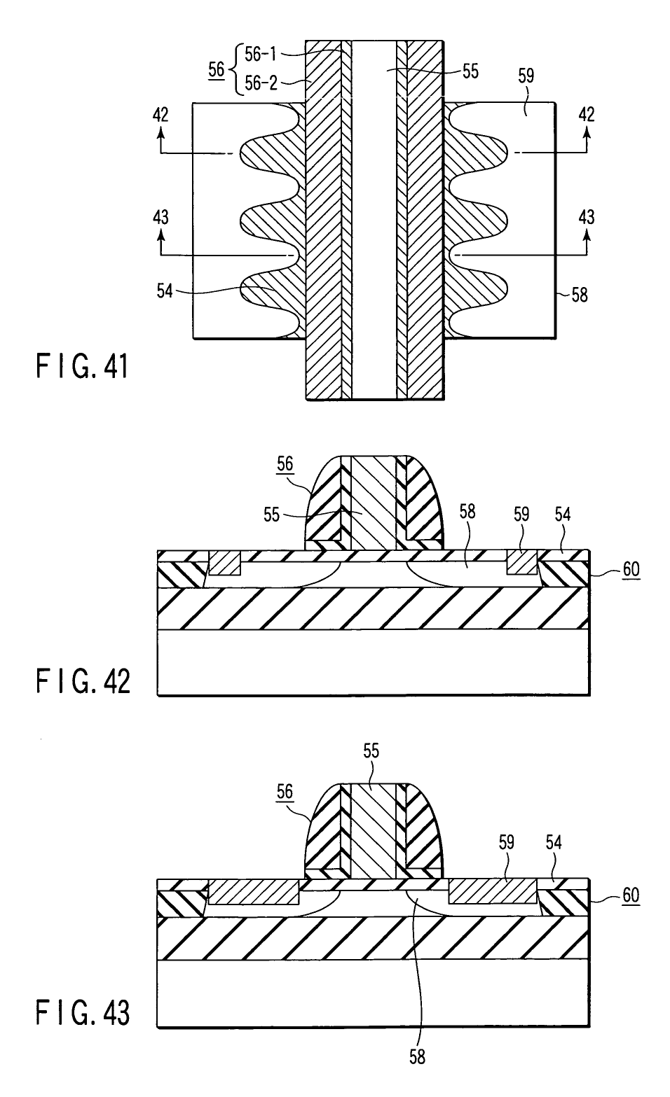

A sixth embodiment will be explained below with reference to FIG. 41 to FIG. 43.

In this embodiment, the shape of region formed with no silicide layer is a shape of wave at the portion adjacent to the gate electrode 55. Accordingly, the part of the silicide layer 59 adjacent to the gate electrode 55 has also a wave shape. Other parts or portions are the same as those in the fifth embodiment, and the description thereof is omitted.

In this embodiment as well, the area of the exposed impurity diffusion region is made larger than that of the silicide layer to provide a region formed with no silicide layer. By doing so, the contact area of the silicide layer and the impurity diffusion region is increased. Therefore, it is possible to effectively improve the current driving ability of the MOSFET.

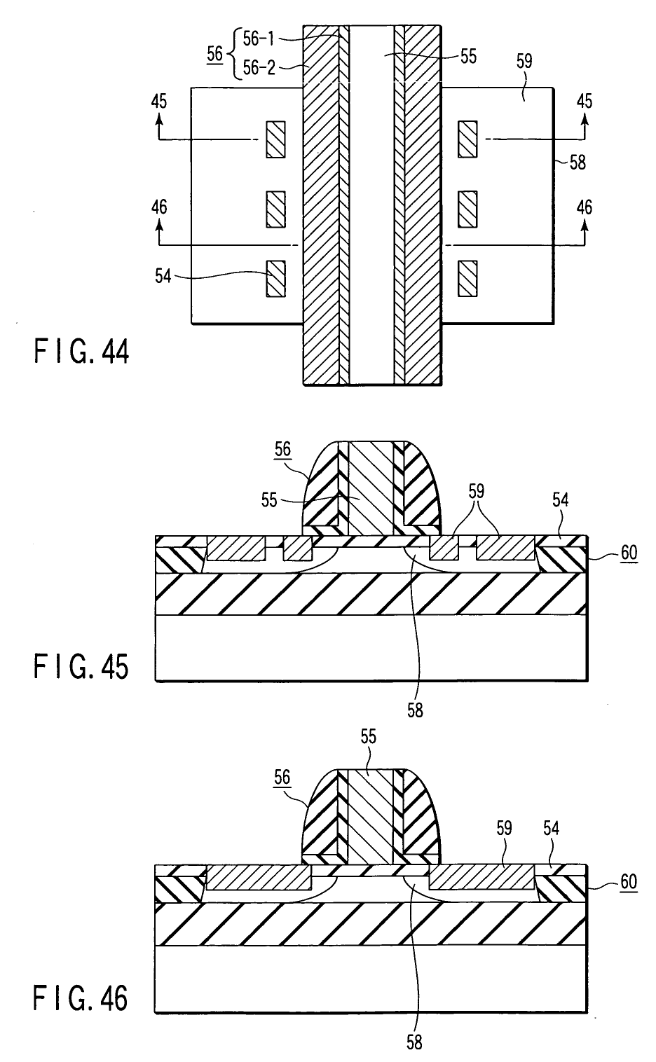

A seventh embodiment will be explained below with reference to FIG. 44 to FIG. 46.

In this embodiment, the shape of region formed with no silicide layer is a square or rectangular shape arranged near the gate electrode 55. Accordingly, the part of the silicide layer 59 near the gate electrode 55 has a shape with an opening arrangement. Other parts or portions are the same as those in the fifth embodiment, and the description thereof is omitted.

Also in this embodiment, the area of the exposed impurity diffusion region is made larger than that of the silicide layer to provide a region formed with no silicide layer. By doing so, the contact area of the silicide layer and the impurity diffusion region is increased. Therefore, it is possible to effectively improve the current driving ability of the MOSFET.

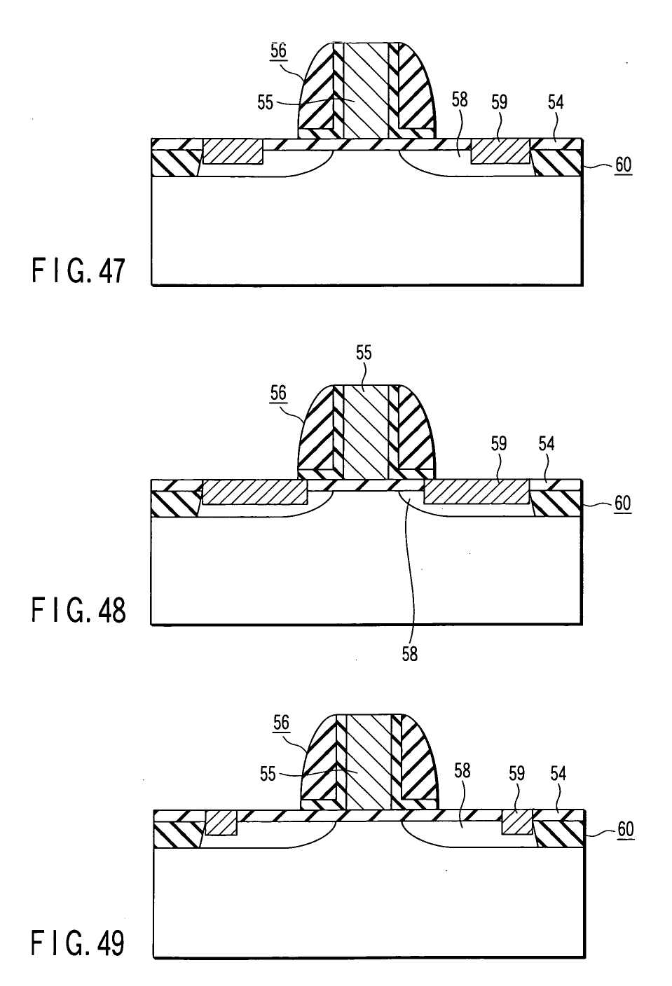

A modification of the fifth embodiment is shown in FIGS. 47 and 48. FIGS. 47 and 48 correspond to FIGS. 39 and 40, respectively. In this modification, a general semiconductor substrate formed of a single layer of silicon as used in the fourth embodiment is used in place of the SOI substrate used in the fifth embodiment. Other parts or portions are the same as those in the fifth embodiment, and the description thereof is omitted.

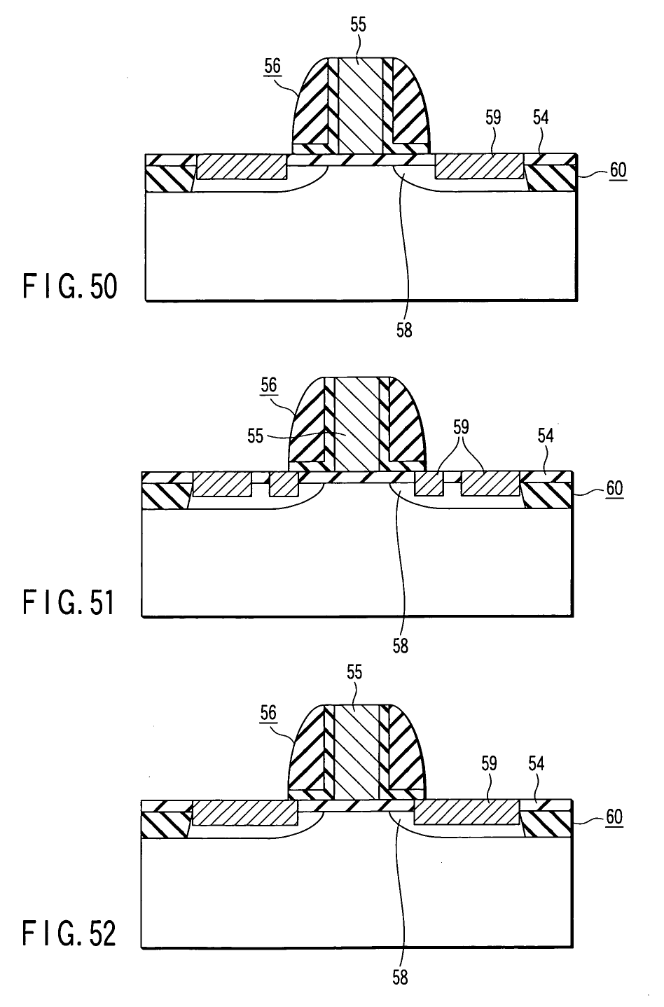

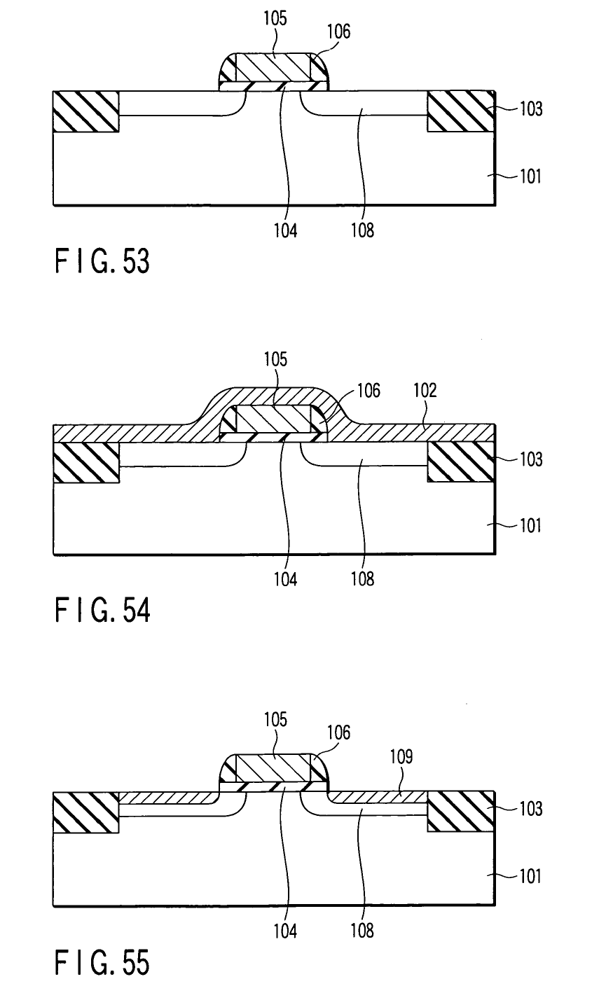

A modification of the sixth embodiment is shown in FIGS. 49 and 50. FIGS. 49 and 50 correspond to FIGS. 42 and 43, respectively. In this modification, a general semiconductor substrate formed of a single layer of silicon as used in the fourth embodiment is used in place of the SOI substrate used in the sixth embodiment. Other parts or portions are the same as those in the sixth embodiment, and the description thereof is omitted.

A modification of the seventh embodiment is shown in FIGS. 51 and 52. FIGS. 51 and 52 correspond to FIGS. 45 and 46, respectively. In this modification, a general semiconductor substrate formed of a single layer of silicon as used in the fourth embodiment is used in place of the SOI substrate used in the seventh embodiment. Other parts or portions are the same as those in the seventh embodiment, and the description thereof is omitted.

In the foregoing embodiments and modifications of the present invention, the method of forming the gate is not limited to those as described. Further, the gate electrode material is not limited to polysilicon; for example, polysilicon containing germanium may be used, or metal may be used. The material used for forming silicide is not limited to nickel; for example, cobalt, titanium and palladium may be used. In order to use the gate insulating film as a mask, the pattern formed on the upper surface of the impurity diffusion region is not necessarily formed on the entire surface thereof. The pattern may be formed on only part of the impurity diffusion region. The pattern shape is not limited to stripes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate;
a source/drain region formed in a surface region of the semiconductor substrate;
a gate insulating film formed on the surface region of the semiconductor substrate;
a gate structure formed on the gate insulating film; and
a silicide layer formed on a region of the source/drain region, which region is not covered by the gate structure, an area of the silicide layer being smaller than that of the region not covered by the gate structure.

2. A semiconductor device according to claim 1, wherein the silicide layer comprises a plurality of divided layer portions.

3. A semiconductor device according to claim 2, wherein the divided layer portions of the silicide layer are arranged in a form of stripe.

4. A semiconductor device according to claim 1, wherein the silicide layer comprises a layer having a portion of a comb form at a region thereof adjacent to the gate electrode structure.

5. A semiconductor device according to claim 1, wherein the silicide layer comprises a layer having a portion of a wave form at a region thereof adjacent to the gate structure.

6. A semiconductor device according to claim 1, wherein having square or rectangular portions in which silicide is not formed are disposed in the suicide layer at a region thereof near the gate structure.

7. A semiconductor device according to claim 1, wherein the silicide layer is made of a suicide of one metal selected from a group of nickel, cobalt, titanium and palladium.

8. A semiconductor device according to claim 1, wherein the gate structure comprises a gate electrode made of polysilicon, polysilicon containing germanium, or a metal.

9. A semiconductor device according to claim 1, in which the gate structure comprises a gate electrode and a gate sidewall insulating film formed on a sidewall of the gate electrode in a gate width direction of the gate electrode, and the silicide layer is formed on a surface of a region, which is not covered by the gate electrode and the gate sidewall insulating film, of the source/drain region.

10. A semiconductor device according to claim 1, wherein the semiconductor substrate comprises an insulating film and a semiconductor layer formed on the insulating film, and the source/drain region is formed in a surface region of the semiconductor layer.

11. A semiconductor device according to claim 10, wherein a channel region having a thickness of 10 nm or less is formed in the semiconductor layer.

12. A semiconductor device according to claim 10, in which the gate structure comprises a gate electrode and a gate sidewall insulating film formed on a sidewall of the gate electrode in a gate width direction of the gate electrode, and the silicide layer is formed on a surface of a region, which is not covered by the gate electrode and the gate sidewall insulating film, of the source/drain region.

13. A method of manufacturing a semiconductor device, comprising:
forming an element formation region and an isolation region defining the element formation region in a semiconductor substrate;
forming a gate insulating film on the semiconductor substrate;
forming a gate electrode on the gate insulating film;
forming a sidewall insulating film on a sidewall of the gate electrode;
forming an impurity diffusion region forming a source/drain region in the semiconductor substrate by using the gate electrode and the sidewall insulating film as a mask;
removing a portion of the gate insulating film by using a resist pattern as a mask to expose a portion of the impurity diffusion region; and
forming a silicide layer on the exposed portion of the impurity diffusion region.

14. The method of manufacturing a semiconductor device according to claim 13, wherein the silicide layer is made of a silicide of one metal selected from a group of nickel, cobalt, titanium and palladium.

15. The method of manufacturing a semiconductor device according to claim 13, wherein the gate electrode is made of polysilicon, polysilicon containing germanium, or a metal.

16. A method of manufacturing a semiconductor device according to claim 13, wherein the semiconductor substrate comprises an insulating film and a semiconductor layer formed on the insulating film, the element formation region and the isolation region are formed in the semiconductor layer, the gate insulating film is formed on the semiconductor layer, and the impurity diffusion region is formed in the semiconductor layer.

17. A method of manufacturing a semiconductor device, comprising:
forming an element formation region and an isolation region defining the element formation region in a semiconductor substrate;
forming a buffer film on the semiconductor substrate;
forming a dummy gate electrode on the buffer film;
forming a sidewall insulating film on a sidewall of the dummy gate electrode;
forming an impurity diffusion region forming a source/drain region in the semiconductor substrate by using the gate electrode and the sidewall insulating film as a mask;
removing a portion of the buffer film by using a resist pattern as a mask to expose a portion of the impurity diffusion region;
forming a silicide layer on the exposed portion of the impurity diffusion region;
forming an interlayer insulating film to cover the silicide layer, the buffer film, the dummy gate electrode and the sidewall insulating film;
planarize the interlayer insulating film to expose an upper surface of the dummy gate electrode;
removing the dummy gate electrode and the buffer film under the dummy gate electrode to form a gate groove; and
forming in the gate groove a gate insulating film and a gate electrode on the gate insulating film.

18. The method of manufacturing a semiconductor device according to claim 17, wherein the silicide layer is made of a silicide of one metal selected from a group of nickel, cobalt, titanium and palladium.

19. The method of manufacturing a semiconductor device according to claim 17, wherein the gate electrode is made of polysilicon, polysilicon containing germanium, or a metal.

20. A method of manufacturing a semiconductor device according to claim 17, wherein the semiconductor substrate comprises an insulating film and a semiconductor layer formed on the insulating film, the element formation region and the isolation region are formed in the semiconductor layer, the buffer film is formed on the semiconductor layer, and the impurity diffusion region is formed in the semiconductor layer.
